(19) United States
(12) Patent Application Publication
(10) Pub. No.: US 2025/0293030 A1
(43) Pub. Date: Sep. 18, 2025

(54) SOLUBILITY SWITCH TOPOGRAPHIC FILL MATERIALS AND METHODS

(71) Applicant: Brewer Science, Inc., Rolla, MO (US)

(72) Inventors: Jakub Koza, Rolla, MO (US); Richard Elsworth Daugherty, JR., Bland, MO (US); Daniel Patrick Sweat, Rolla, MO (US); Joyce A. Lowes, Rosebud, MO (US); Jinhua Dai, Rolla, MO (US); Stephen Smith, Rolla, MO (US)

(21) Appl. No.: 19/082,407

(22) Filed: Mar. 18, 2025

Related U.S. Application Data
(60) Provisional application No. 63/566,428, filed on Mar. 18, 2024.

(51) Int. Cl. H01L 21/027; G03F 7/004; G03F 7/16; G03F 7/32; G03F 7/38; H01L 21/768

(52) U.S. Cl. CPC H01L 21/0276; G03F 7/0045; G03F 7/168; G03F 7/325; G03F 7/38; H01L 21/76828; H01L 21/76837

(57) ABSTRACT

Materials and methods are described for filling deep trenches and other topography using a single coating of a topographic fill material and a single develop back step while maintaining a thickness that can be controlled and is sufficient to fill very deep topographies to the extent needed for lithographic patterning. The materials are designed for selective changes to their solubility, and the methods involve using this feature to achieve selective removal of desired amounts of the topographic fill material at various stages of the process. This allows more efficient processing and higher throughput for lithographic applications in which a photoresist is applied over deep topography while addressing the problems of resist cracking, bending, peeling, or scumming.

### CROSS-REFERENCE TO RELATED APPLICATIONS

The present application claims the priority benefit of U.S. Provisional Patent Application Ser. No. 63/566,428, filed Mar. 18, 2024, entitled SOLUBILITY SWITCH TOPOGRAPHIC FILL MATERIALS AND METHODS, the entirety of which is incorporated by reference herein.

### BACKGROUND

### Field

The present invention relates generally to materials and methods for forming microelectronic structures, and more particularly to gap fill materials and methods for performing processes on substrates having deep trenches or other deeply recessed topographic features.

### Description of Related Art

It is sometimes necessary in the semiconductor industry to form lithographic patterns across relatively wide and deep recessed areas such as deep trenches. However, it is difficult to apply a photoresist over deep trenches or other recessed topography because this often results in resist peeling, cracking, bending, or scumming in the bottom of the recessed areas. A conventional way to address this problem is to use a developable bottom antireflective coating (DBARC) to fill the topography before applying the photoresist. However, this solution requires multiple coat/bake/develop steps to achieve the amount of topographic filling needed and to clear the DBARC material off the substrate surfaces surrounding the recessed areas. This has a substantial negative impact on throughput. This conventional DBARC process is also not suitable for some of the deeper topographies involved in some of the most recent processes.

### SUMMARY

The present disclosure is broadly concerned with a topographic fill method. The method comprises applying a fill composition over a pattern comprising a plurality of gaps in a substrate so as to deposit the fill composition in at least some of the gaps. The fill composition has a temperature at which it begins to crosslink, and comprises a component dispersed or dissolved in a solvent system having an evaporation temperature. The component is chosen from one or more of polymers, oligomers, or monomeric compounds. The fill composition is heated to about the evaporation temperature or higher, but lower than the crosslinking temperature, so as to remove at least some of the solvent system and form a dried composition. The dried composition is contacted with a developer solvent so as to remove at least some of the dried composition. After contacting with a developer solvent, one of (a) or (b) is carried out:
(a) heating the dried composition to the crosslinking temperature or higher so as to cause the component to crosslink and form a crosslinked fill material that is substantially insoluble in the developer solvent; and forming a photoresist layer on the crosslinked fill material; or
(b) forming a photoresist layer on the dried composition; and then heating the dried composition to the crosslinking temperature or higher so as to cause the component to crosslink and form a crosslinked fill material that is substantially insoluble in the developer solvent.

The photoresist layer is selectively exposed to radiation, and the crosslinked fill material is heated at a temperature that is about 10° C. or more above the crosslinking temperature for a sufficient time so as to cause the crosslinked fill material to become soluble in the developer solvent and form a soluble fill material.

### BRIEF DESCRIPTION OF THE DRAWINGS

FIG. 1 is a schematic depiction (not to scale) of one solubility-switching method described herein;

FIG. 2 is a schematic drawing that shows how “W” and “D” are defined;

FIG. 3 is a graph comparing the thickness loss to the bake temperature of the material described in Example 1;

FIG. 4 is a graph comparing the strip rate in propylene glycol monomethyl ether acetate to the bake temperature of the material described in Example 1;

FIG. 5 is a graph comparing the thickness loss to the bake temperature of the material described in Example 2;

FIG. 6 is a graph comparing the develop rate in tetramethylammonium hydroxide to the bake temperature of the material described in Example 2;

FIG. 7 is a graph comparing the strip rate in propylene glycol monomethyl ether acetate to the bake temperature of the material described in Example 2; and

FIG. 8 is a graph comparing the thickness loss to thermal acid generator loading of the material in Example 2.

### DETAILED DESCRIPTION

The present disclosure is concerned with novel methods to address the issues associated with deep topography by use of a fill composition whose solubility and other properties can be altered at different processing stages. The disclosure also provides several chemistries for accomplishing these alterations.

### Solubility Switch Methods

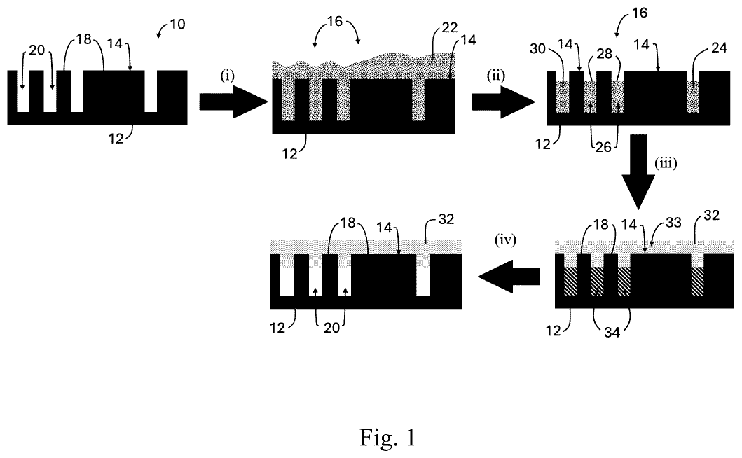

FIG. 1 provides a schematic depiction of one process flow according to the present disclosure. Referring to the top left image of FIG. 1, a microelectronic structure 10 is shown (not to scale). Structure 10 comprises a substrate 12 having an upper surface 14. While any microelectronic substrate can be utilized, a semiconductor substrate is a preferred substrate 12. Examples of suitable substrates 12 include those formed of one or more of the following materials: silicon, SiGe, SiO₂, Si₃N₄, SiON, aluminum, tungsten, tungsten silicide, gallium arsenide, gallium nitride, germanium, tantalum, tantalum nitride, Ti₃N₄, hafnium, HfO₂, ruthenium, indium phosphide, aluminum gallium arsenide, aluminum indium phosphide, indium gallium phosphide, or glass. Additionally, one or more optional intermediate layers (not shown) may be formed on substrate surface 14. One such intermediate layer, for example, comprises a TiN layer.

Although the substrate 12 can be of any shape, it is often circular in shape, such as a circular wafer. Suitable substrates 12 include device wafers such as those whose surfaces comprise arrays of devices such as integrated circuits, MEMS, microsensors, power semiconductors, light-emitting diodes, photonic circuits, interposers, embedded passive devices, and other microdevices fabricated on or from silicon and other semiconducting materials.

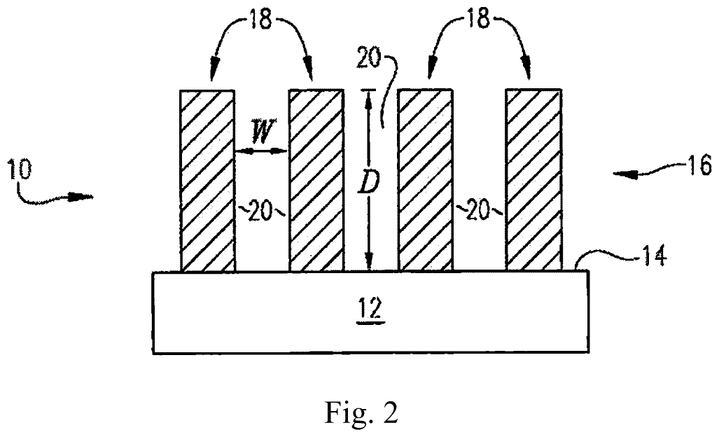

In the embodiment illustrated, structure 10 further comprises a topographical pattern 16 (e.g., lithographically formed) in substrate surface 14 (or on any intermediate layers that might be present on substrate surface 14). However, in some embodiments (see, for example, FIG. 2, where like parts are similarly numbered), topographical pattern 16 may be formed on upper surface 14 of substrate 12. Again referring to FIG. 1, topographical pattern 16 includes topographic features 18, which define a plurality of gaps 20. Examples of topographic features 18 include lines, gates, raised features, and/or pillars. Gaps 20 can be, for example, deep trenches, valleys, holes, or other recessed areas. Also, as illustrated, the topographic features 18 are not necessarily evenly distributed over substrate surface 14. Instead, if needed for a particular application, the topography is suitably grouped into relatively denser areas (in which topographic recessed areas are positioned relatively closer to one another) and relatively isolated areas (in which topographic recessed areas are spaced relatively farther from one another).

Gaps 20 can be holes (e.g., via and/or contact holes), trenches, spacing between lines, pores in a porous material, and/or any other spacing or void. Gaps 20 have respective widths “W” and depths “D,” as shown in FIG. 2. The respective widths “W” of gaps 20 can be the same or different widths and are typically quite small, e.g., less than about 100 nm, preferably less than about 75 nm, more preferably less than about 50 nm, even more preferably less than about 25 nm, and most preferably less than about 10 nm. The respective depths “D” of gaps 20 can be the same or different and are comparatively deep, such as about 10 nm to about 20 μm, preferably about 100 nm to about 15 μm, more preferably about 200 nm to about 10 μm, and even more preferably about 200 nm to about 2,000 nm. In some embodiments, “D” is at least about 8 μm while “W” is about 3 μm wide.

The gaps 20 have a high aspect ratio, where “aspect ratio” is defined as D/W. Aspect ratios used in the process described herein are generally about 3 or greater, preferably about 5 or greater, more preferably about 10 or greater, and even more preferably about 15 or greater. Typical ranges of aspect ratios are about 3 to about 100, about 5 to about 50, about 7 to about 40, and even more preferably about 10 to about 30.

As shown at arrow (i) of FIG. 1, a fill composition 22 is applied to topographical pattern 16 so that at least some of the fill composition 22 is deposited in at least some of the gaps 20 in the pattern. In some embodiments, the fill composition 22 is deposited in substantially all of the gaps 20. In some embodiments, the fill composition 22 substantially fills some or all of the gaps 20 in the pattern. In some embodiments, there might be one or more intermediate layers (not shown) first applied to topographical pattern 16, and the fill composition 22 would be applied to the uppermost (i.e., last) such intermediate layer. Examples of such intermediate layers include one or more of high-carbon layers, silicon hardmasks, metal hardmasks, metals, or dielectrics.

Regardless of whether an intermediate layer was first applied to topographical pattern 16, the fill composition 22 broadly includes a component (e.g., polymer, oligomer, and/or low molecular weight or other monomeric compounds) dissolved or dispersed in a solvent system. The fill composition 22 can be applied by any known application method, with one preferred method being spin coating at speeds of about 800 rpm to about 4,000 rpm, preferably about 1,000 rpm to about 2,500 rpm, and more preferably about 1,000 rpm to about 2,000 rpm. Spin coating times are typically about 30 seconds to about 180 seconds, and preferably about 30 seconds to 60 seconds. Preferably, the selected fill composition 22 has good spin bowl compatibility, meaning that it does not react or form a precipitate with common photoresist solvents such as PGME, PGMEA, ethyl lactate, cyclohexanone, or combinations thereof.

After the fill composition 22 is applied, it is preferably subjected to a “soft bake.” As used herein, a soft bake refers to heating the fill composition 22 to approximately the evaporation temperature or higher of the solvent system, and preferably lower (e.g., at least 5° C., more preferably at least 10° C. lower) than the crosslinking temperature of the fill composition 22. It is understood that the temperature at which a solvent system evaporates depends on a range of factors including pressure and composition of the environment into which the solvent evaporates. As used herein, the evaporation temperature refers to a temperature that dries solvent from the fill composition under the applicable process conditions. Thus, the temperature of the evaporation temperature for a particular fill composition may vary depending on the process conditions. While the soft bake temperature also depends upon the makeup of the particular fill composition and/or for optimization of recess processes to be performed, typical soft bake temperatures are less than about 190° C., more preferably about 170° C. to about 190° C., and even more preferably about 175° C. to about 185° C., for a time period of about 30 seconds to about 120 seconds, and more preferably about 45 seconds to about 60 seconds.

Regardless of the bake temperature, the soft bake results in at least some of the solvent system being removed from the fill composition 22 so as to at least partially dry the fill composition 22 and form a dried fill composition 24. In some embodiments, the soft bake results in at least about 50%, preferably at least about 75%, more preferably at least about 95%, and even more preferably about 100% of the solvent system being removed from the fill composition 22.

Additionally, it is preferred that little to no crosslinking takes place during the soft bake. That is, the dried fill composition 24 is substantially soluble in developer solvents, including alkaline developers, such as tetramethylammonium hydroxide (TMAH), and/or organic solvents, such as propylene glycol methyl ether acetate (PGMEA), propylene glycol methyl ether, ethyl lactate, n-butylacetate, and/or others. As used herein, solubility in an alkaline developer is determined by coating the particular fill composition onto a flat substrate (i.e., a substrate without topography) and baking at a temperature of about 190° C. for about 60 seconds. The thickness of the layer is measured via ellipsometry. The developer (e.g., about 2.3 to about 2.6% TMAH solution) is puddled on the coated substrate for about 20 seconds and spun dry. The thickness of the layer is then measured again to determine any thickness loss, which then is equated to solubility. If a material is soluble, the thickness loss will be at least about 95%, preferably at least about 99%, and more preferably about 100%. If a material is insoluble, there is less than about 5% thickness loss, more preferably less than about 1% thickness loss, and even more preferably about 0% thickness loss.

After soft baking and as shown in arrow (ii) of FIG. 1, the dried fill composition 24 can be developed back, stripped, or recessed with a fab-friendly solvent, such as those mentioned above. It is preferred that plasma etching is not used to remove or thin the dried fill composition 24. The process conditions for the soft bake and removal of the dried fill composition 24 are preferably coordinated to produce a calibrated topographic fill material removal process in which the height of the topographic fill material remaining in the recessed areas is substantially uniform and controlled. For example, the removal rate of the dried fill composition 24 can vary with the temperature of the soft bake. Thus, by selecting the optimal soft bake temperature and/or other process conditions, the desired amount of soft-baked dried fill composition 24 can be removed efficiently in relatively little time (e.g., about 1 minute). The dried fill composition 24 remaining in the gaps 20 at the end of this step forms respective plugs 26. Each plug 26 has a height 28 within one or more gaps 20, and that height 28 can be varied relative to the upper surface 14. In the upper right image of FIG. 1, the heights 28 of the plugs 26 are recessed below the upper surface 14. However, in some embodiments (not shown), the plugs 26 have heights 28 that are approximately flush or even with upper surface 14.

After the desired amount of dried fill composition 24 has been removed, the remaining dried fill composition 24 is preferably subjected to a “cure bake.” As used herein, a cure bake refers to heating the dried fill composition 24 to approximately the curing temperature or higher of the dried fill composition 24. At the same time, it is preferred that this temperature is lower (e.g., at least 5° C., more preferably at least 10° C. lower) than the thermal decomposition temperature of the dried fill composition 24. It will be appreciated that the curing temperature will vary depending on the specific composition of the dried fill composition 24, as well as the particular crosslinking mechanism. In some embodiments, for example, the cure bake temperature is about 190° C. to about 200° C., and preferably for a time period of from about 30 seconds to about 120 seconds, and more preferably about 45 seconds to about 60 seconds. During the cure bake, the polymer and/or oligomer in the dried fill composition 24 crosslinks and form a crosslinked fill material 30. The crosslinked fill material 30 is now solvent- and photoresist-compatible, meaning that it is substantially insoluble in typical photoresist solvents (e.g., PGMEA, propylene glycol methyl ether (PGME), ethyl lactate (EL), ethylene glycol monoethyl ether acetate) and undergoes substantially no intermixing with a photoresist that will ultimately be applied over the top of the crosslinked fill composition. Additionally, the crosslinked fill composition 30 is now substantially insoluble in alkaline developers such as the ones mentioned previously.

Next, further processing can be performed on the structure 10, with that processing being selected by the user, depending on the particular application. Typically, “further processing” will include forming a photoresist layer 32 on the crosslinked fill material 30 (arrow (iii) of FIG. 1). The photoresist layer 32 can be formed from any commercial photoresist material (positive tone or negative tone) and by any conventional method, with one preferred method being spin coating the photoresist composition at speeds of about 350 rpm to about 4,000 rpm (preferably about 1,000 rpm to about 2,500 rpm) for a time period of about 10 seconds to about 60 seconds (preferably about 10 seconds to about 30 seconds). The photoresist layer is then optionally post-application baked (“PAB”) at a temperature of at least about 70° C., preferably about 80° C. to about 150° C., and more preferably about 100° C. to about 150° C., for time periods of about 30 seconds to about 120 seconds. The average thickness of the photoresist layer after baking is typically about 5 nm to about 120 nm, preferably about 10 nm to about 50 nm, and more preferably about 20 nm to about 40 nm. As used herein, average thickness is determined by taking the average of thickness measurements at five different locations of the particular layer, with those thickness measurements being obtained using ellipsometry.

It will be appreciated that the photoresist layer 32 contacts, and is supported by, the plugs 26. This arrangement supports the photoresist layer 32 and helps prevent strain, cracking, and/or deformation of the photoresist layer 32 that might otherwise occur if the photoresist layer were not supported by plugs 26 and instead allowed to sag into gaps 20. In the embodiment illustrated in FIG. 1, the photoresist layer 32 extends a small amount into each gap 20, which may be desirable in certain applications, for example, by helping better anchor the photoresist layer 32 to the substrate 12. Additionally, the difficulties often encountered when removing resist material from the bottoms of gaps 20 are avoided because the crosslinked fill material 30 occupies that space and obstructs flow of the photoresist composition into the bottoms of the gaps 20.

The photoresist layer 32 is subsequently patterned by exposure to radiation, and preferably with only one exposure step. In one embodiment, the single exposure is carried out at an exposure focal plane that is located above upper surface 14 and below photoresist top surface 33. The dose will depend on the particular process, but typical doses are about 10 mJ/cm² to about 200 mJ/cm², preferably about 15 mJ/cm² to about 100 mJ/cm², and more preferably about 20 mJ/cm² to about 50 mJ/cm². More specifically, the photoresist layer 32 is exposed using a mask (not shown) positioned above the surface of the photoresist layer 32. The mask has areas designed to permit the radiation to reflect from or pass through the mask and contact the surface of the photoresist layer 32. The remaining portions of the mask are designed to absorb the light to prevent the radiation from contacting the surface of the photoresist layer 32 in certain areas. Those skilled in the art will readily understand that the arrangement of reflecting and absorbing portions is designed based upon a desired pattern to be formed in the photoresist layer 32 and ultimately in the substrate 12 or any layers between the photoresist layer 32 and substrate 12.

After exposure, the photoresist layer is preferably subjected to a post-exposure bake (“PEB”). The PEB temperature can be selected for the particular photoresist material used to form photoresist layer 32, however, in one embodiment, it is preferred that the PEB temperature be higher than the PAB temperature, the cure bake temperature, or both so as to induce a “solubility switch” in crosslinked fill material 30. That is, this heating step, referred to herein as a “solubility switch bake,” causes a chemical and/or physical change in crosslinked fill material 30, forming a solubility-switched material 34, with that solubility-switched material 34 being soluble in alkaline developers, such as those mentioned previously. In alternative embodiments, the solubility switch bake can be a separate bake after the PEB, such as in those situations where the recommended PEB temperatures are lower than those needed to induce the solubility switch.

Whether the solubility switch bake is combined with the PEB or carried out as a separate heating step after the PEB, the temperature of the solubility switch bake can vary depending on the composition of the selected fill composition 22 and the solubility-switching chemistries of the particular fill composition 22. However, in some embodiments, the solubility switch bake is conducted at a temperature above about 210° C., preferably about 210° C. to about 250° C., and more preferably about 215° C. to about 240° C., typically for a time period of about 30 seconds to about 120 seconds, and preferably about 45 seconds to about 60 seconds. Additionally, the mechanism by which the solubility switch takes place will depend upon the chemistry, three types of which are described in detail below.

Referring to arrow (iv) of FIG. 1, the remaining solubility-switched material 34 is stripped using PGMEA, TMAH, or other suitable developer solvent, leaving gaps 20 substantially free, and preferably completely free, of solubility-switched material 34. Preferably at least about 95% of the solubility-switched material 34 is removed from gaps 20 and the substrate surface 14, more preferably at least about 99%, and even more preferably at least about 99.9% (hereinafter referred to as “% removal”). The % removal of solubility-switched material 34 is determined by coating and baking the fill composition 22 as described above on a flat substrate (i.e., one having no topography), and measuring the average thickness of the crosslinked fill layer, such as via ellipsometry. The layer is then baked at 220° C. for about 60 seconds, and the average thickness of the fill layer is measured again and the % removed calculated. Residual material quantities may also be determined using analytical techniques such as XPS.

If photoresist layer 32 is a positive working resist, the portions thereof that were exposed to radiation are simultaneously removed/developed with the solubility-switched material 34 while the unexposed portions remain. Conversely, if photoresist layer 32 is a negative working resist, the portions thereof that were not exposed to radiation are simultaneously removed/developed with the solubility-switched material 34, while the exposed portions remain. Regardless, the patterned photoresist remains on top of the topographic substrate, and that pattern may be transferred through any of the various layers that might have been used and/or into the substrate 12, depending on the embodiment and the particular structure being formed. This pattern transfer can take place via plasma etching (e.g., CF₄ etchant, O₂ etchant) or a wet etching or developing process.

Further processing can be carried out at this stage, depending on the use, including one or more of polishing, chemical-mechanical planarization, ion implantation, and/or metallization. In one embodiment, ion implantation is carried out by implanting ions (e.g., boron ions, phosphorus ions, arsenic ions, nitrogen ions, carbon ions, and/or metal ions like titanium ions and tungsten ions) in the bottom of one or more gaps 20. This process can help address the prior art ion implantation problem where residual photoresist at the bottom of gaps 20 might have otherwise interfered with ions implanting in the bottom of gaps 20.

Fill testing can be performed by coating the particular fill composition 22 on suitable substrates and viewing a cross-section of the features. Typical substrates for checking fill performance are made via formation of about 500-nm deep (i.e., “D” as defined previously) silicon oxide trenches patterned to about 180 nm feature width at a density of about 1:1. The feature size is reduced by deposition of about 80 nm of silicon nitride via a CVD process. The resulting features range from about 20 nm to about 10 nm wide (“W”) trenches. The fill composition 22 to be tested is spin-coated and baked to crosslink according to the parameters given above. Substrates are examined via SEM for adequate filling without voids or delamination and with minimal residues development. The crosslinked fill material 30 should not have voiding, bubbles, or delamination from the side walls after the standard spin and bake process.

Advantageously, the disclosed fill compositions are able to completely fill the gaps 20 when “D” (see FIG. 2) is about 10 μm or less and “W” is about 500 nm or less, preferably when “D” is about 500 nm or less and “W” is about 100 nm or less, and more preferably when “D” is about 200 nm or less and “W” is about 50 nm or less.

In some embodiments, one, two, three, or all four of the fill composition 22, dried fill composition 24, crosslinked fill material 30, or solubility-switched material 34 are non-photosensitive. As used herein, non-photosensitive means that a pattern cannot be defined in a layer of the material when it is exposed to about 1 J/cm², and/or the composition or layer comprises less than about 0.01% by weight photoacid generator, more preferably less than about 0.005% by weight photoacid generator, and more preferably about 0% by weight of photoacid generator, based on the weight of the composition or layer.

Additionally or alternatively, in some embodiments it is preferred that process is a single-photoresist process. That is, the only photosensitive composition or layer used in combination with the fill composition 22 throughout the above-described process is the photoresist layer 32 described previously.

There are several variations to the foregoing general method that can be employed. For example, air gaps can be formed in an alternative process using the fill compositions described herein. In this variation, the process shown in FIG. 1 would generally be followed until arrow (iii) where photoresist layer 32 would instead be a support material layer 32. The support material layer 32 can be formed as described above with respect to the photoresist or other layers and can be any type of layer desired by the end user for the particular process, including CVD, ALD, or spin-on layers. Thus, when solubility-switched material 34 is removed as previously described, air gaps 20 are formed under the support material layer 32 where solubility-switched material 34 used to be disposed. Thus, the support material layer 32 serves as a “cap” over the air gaps 20. Further processing can be carried out on layer 32, as desired for the particular application. Advantageously, this process provides a method for creating air gaps around features having a high aspect ratio, which can be desirable for certain types of further processing, while avoiding pattern collapse.

A further variation to the above-described general process is that the timing of the solubility switch can be altered. That is, instead of the solubility-switched material 34 being formed after the formation of photoresist layer 32 (or support layer 32, in an alternative embodiment), in this variation, the solubility-switched material 34 is formed before the photoresist layer 32 is formed, causing solubility-switched material 34 to become developable in TMAH and other alkaline developers but still remain insoluble in solvents such as PGMEA. As a result, the solubility-switched material 34 will not intermix with the photoresist solvent and is easily removable by the TMAH developer at the same time the pattern in the photoresist is developed.

### Solubility Switch Chemistries

The fill compositions utilized in the above methods can be based on conventional topographic fill materials and/or antireflective coatings that already include, or are chemically modified to include, a solubility switch such as one of the types described below. In general, the composition comprises a component chosen from polymers, oligomers, and/or low-molecular-weight or other monomeric compounds, dissolved or dispersed in a solvent system.

The component selection is described in more detail with each particular embodiment, but the component is generally present in the fill composition at a level of about 0.001% by weight to about 50% by weight, more preferably about 0.005% to about 20%, more preferably about 0.01% by weight to about 5% by weight, and even more preferably about 0.1% by weight to about 3% by weight, based on the total weight of the fill composition taken as 100% by weight.

The total solids in the composition are typically about 1% by weight to about 50% by weight, preferably about 1% by weight to about 20% by weight, more preferably about 3% by weight to about 15% by weight, and even more preferably about 5% by weight to about 8% by weight, based on the total weight of the fill composition taken as 100% by weight.

The solvent system comprises one or more solvents, with suitable solvents including those chosen from one or more of propylene glycol methyl ether acetate, propylene glycol methyl ether, propylene glycol ethyl ether, cyclopentanone, cyclohexanone, anisole, acetophenone, γ-butyrolactone, or mixtures thereof. The solvent system is generally present at levels of at least about 50%, preferably about 80% by weight to about 99% by weight, more preferably about 85% by weight to about 97% by weight, and even more preferably about 92% by weight to about 95% by weight, based on the total weight of the fill composition taken as 100% by weight.

In some embodiments, a surfactant may be included in the fill composition to improve coating quality. Nonionic surfactants such as R30N (DIC Corporation, Japan) and FS3100 (The Chemours Company FC, LLC, USA) are preferred. When used, the surfactant is preferably present in the particular fill composition at a level of about 0.1% by weight to about 1% by weight, and more preferably about 0.2% by weight to about 0.5% by weight, based upon the total weight of the component (total polymer, oligomer, and/or low-molecular-weight or other monomeric compounds) taken as 100% by weight.

### 1. Imidization

In this embodiment, the component of the fill composition comprises a diamic acid (considered to be an oligomer herein), a polyamic acid, or mixtures thereof.

Suitable diamic acids can be commercially obtained, or they can be synthesized, such as by reacting one or more dianhydrides with one or more monoamines, or by reacting one or more monoanhydrides with one or more diamines, in an appropriate reaction solvent system, which can include only one solvent or multiple solvents.

In one embodiment where the diamic acid is synthesized, one or more dianhydrides and one or more monoamines are reacted in a solvent system. Suitable dianhydrides include those chosen from benzophenone-3,3′4,4′-tetracarboxylic dianhydride, 4,4′-oxydiphthalic dianhydride, 9,9-bis(3,4-dicarboxyphenyl) fluorene dianhydride, or combinations thereof. Suitable monoamino compounds are preferably crosslinkable and include those chosen from 2-vinylaniline, 4-vinylaniline, 2-allylaniline, 4-allylaniline, 3-ethynylaniline, 4-ethynylaniline, 2-ethynylaniline, or combinations thereof. Examples of suitable reaction solvents include those chosen from dimethylformamide, dimethylacetamide, N-methyl-2-pyrrolidone, gamma-butyrolactone, propylene glycol monomethyl ether acetate, propylene glycol monomethyl ether, propylene glycol ethyl ether, cyclopentanone, or combinations thereof. The molar ratio of the monoamino compound to dianhydride is preferably about 2:1 to about 2.2:1, and more preferably about 2:1 to about 2.1:1.

In another embodiment where the diamic acid is synthesized, it is formed by reacting one or more diamines with one or more monoanhydrides in a solvent system. Suitable diamines include those chosen from 4,4′-oxydianiline, bis(4-aminophenyl) sulfone, 9,9-bis(4-aminophenyl) fluorene, or combinations thereof. Suitable monoanhydride compounds are preferably crosslinkable and include those chosen from maleic anhydride, 4-cyclohexene-1,2-dicarboxylic anhydride, 5-norbornene-2,3-dicarboxylic anhydride, 4-ethynyl phthalic anhydride, 4-methylethynyl phthalic anhydride, 4-phenylethynyl phthalic anhydride, or combinations thereof. Suitable reaction solvents include those discussed above. The molar ratio of the monoanhydride compound to diamine is preferably from about 2:1 to about 2.2:1, and more preferably from about 2:1 to about 2.1:1.

Regardless, the reaction is a polycondensation reaction carried out under nitrogen with stirring, preferably at a temperature of about 10° C. to about 50° C., and more preferably about 20° C. to about 40° C., for about 12 hours to about 36 hours, and more preferably about 16 to 24 hours. The formed diamic acids preferably have a weight average molecular weight of preferably less than about 1,000 Daltons, more preferably from about 500 Daltons to about 1,000 Daltons, and even more preferably from about 600 Daltons to about 800 Daltons.

Suitable polyamic acids can be commercially obtained, or they can be synthesized, such as by reacting one or more anhydrides and/or dianhydrides with one or more diamines in an appropriate reaction solvent system, which can include only one solvent or multiple solvents.

In embodiments where the polyamic acid is synthesized, suitable dianhydrides comprise aromatic moieties, with preferred aromatic dianhydrides having flexible structures. “Flexible structures” as used herein describes structures with aliphatic linkages that allow the bonds in the structure to rotate and flex. Examples of such dianhydrides include those chosen from benzophenone-3,3′4,4′-tetracarboxylic dianhydride, 4,4′-biphthalic dianhydride, 4,4′-oxydiphthalic dianhydride, 9,9-bis(3,4-dicarboxyphenyl) fluorene dianhydride, or combinations thereof.

Suitable diamines for polyamic acid synthesis comprise aromatic moieties, with preferred aromatic diamines having flexible structures. Examples of such diamines include those chosen from 4,4′-oxydianiline, bis(4-aminophenyl) sulfone, 9,9-bis(4-aminophenyl) fluorene, or combinations thereof.

Polymerization can be carried out in any suitable reaction solvent systems, which include those discussed previously with the diamic acid synthesis.

In embodiments where it is desirable to obtain polyamic acids with amino terminal groups (or at least primarily amino terminal groups), the ratio of dianhydride to diamine utilized is preferably about 1:3 to about 4:5, and more preferably about 1:3 to about 2:3. In embodiments where it is desirable to obtain polyamic acids with anhydride terminal groups (or at least primarily anhydride terminal groups), the ratio of dianhydride to diamine is preferably from about 4:3 to about 14:3, and more preferably from about 5:3 to about 10:3. In either embodiment, it is preferred that the polyamic acids have a weight average molecular weight of about 500 Daltons to about 9,000 Daltons, and preferably about 2,000 Daltons to about 7,000 Daltons, as determined by GPC.

The dianhydride and diamine monomers are preferably dissolved or dispersed in the reaction solvent in an amount of about 5% by weight to about 20% by weight, more preferably about 7% by weight to about 15% by weight, and most preferably about 10% by weight, based upon the total weight of the reaction system by weight. A polycondensation reaction is carried out under nitrogen with stirring at a temperature of about 10° C. to about 40° C., and preferably about 20° C. to about 30° C., for about 12 hours to about 36 hours, and preferably from about 16 hours to about 24 hours.

The polyamic acids can be endcapped, if desired. In embodiments where the polyamic acids are terminated with amino groups, the endcapper is preferably an anhydride such as those chosen from acetic anhydride, phthalic anhydride, succinic anhydride, trimellitic anhydride, 1,2-cyclohexanedicarboxylic anhydride, 4-cyclohexene-1,2-dicarboxylic anhydride, 5-norbornene-2,3-dicarboxylic anhydride, 4-ethynyl phthalic anhydride, 4-methylethynyl phthalic anhydride, 4-phenylethynyl phthalic anhydride, or combinations thereof.

In embodiments where the polyamic acids are terminated with anhydride groups, the endcapper is preferably a compound comprising an amino group, such as aniline. Compounds comprising an aniline moiety are particularly preferred, including those chosen from 2,5-dimethoxyaniline, 3,5-dimethoxyaniline, 3,4,5-trimethoxyaniline, 5-amino-1-naphthol, 4′-aminoacetophenone, 1-aminoanthraquinone, 3-ethynylaniline, 4-ethynylaniline, 2-ethynylaniline, or combinations thereof.

Regardless of the endcappers selected, the endcapping reaction is carried out under nitrogen with stirring at a temperature of about 10° C. to about 40° C., and preferably about 20° C. to about 30° C., for about 12 hours to about 36 hours, and more preferably about 16 hours to 24 hours.

The resulting polyamic acids have a weight average molecular weight of about 500 Daltons to about 9,000 Daltons, and preferably about 2,000 Daltons to about 7,000 Daltons, as determined by GPC.

In addition to the diamic acid and/or polyamic acid, the fill composition of this embodiment includes a crosslinker. Suitable crosslinkers are preferably multi-functional (e.g., di-, tri-, tetra-functional) and include reactive groups such as those chosen from epoxies, aminoplasts (e.g., those sold under the name Powderlink®, Cymel® 1170, or Cymel® 303), vinyl ethers, or combinations thereof. Preferred crosslinkers includes those chosen from tetraglycidyl methylene dianiline based, tetra-functional epoxy resin crosslinkers (e.g., ARALDITE® MY 721, available from Huntsman) or combinations thereof.

The crosslinker is preferably present at levels of about 5% by weight to about 50% by weight, more preferably about 5% by weight to about 25% by weight, and even more preferably about 5% by weight to about 15% by weight, based on the total weight of polyamic acid and diamic acid solids taken as 100% by weight.

Other compositions suitable for use herein are described in U.S. Pat. No. 7,261,997, the entire contents of which are hereby incorporated by reference.

The prepared formulation is used as fill composition 22, discussed previously with respect to the solubility switch method. This material can be soft baked at temperatures up to about 130° C. for about 45 seconds to about 60 seconds, with minimal to no crosslinking. After this soft bake, the material can be developed (e.g., using TMAH) or stripped using a solvent to reduce its thickness, as explained previously. Moreover, the strip rate can be controlled to facilitate removal of the desired thickness in the desired time by varying the temperature of the soft bake.

When this fill material is baked at a cure bake (e.g., about 180° C. to about 200° C. for about 45 seconds to about 60 seconds), a crosslinking reaction occurs between the carboxyl groups of the diamic or polyamic acid and the functional groups on the crosslinker (e.g., epoxy groups, vinyl groups, hydroxymethyl groups) of the crosslinker to form amic esters. After the cure bake, the material cannot be developed by TMAH and cannot be stripped by solvents, as explained with the method of above. However, when the material is subjected to the solubility switch bake (e.g., at a temperature above about 210° C. for about 45 seconds to about 60 seconds), the amic esters are imidized, and the resulting imide (which may be a diimide and/or polyimide) can be stripped by a solvent to completely remove the material.

### 2. Decrosslinking

In this embodiment, the component of the fill composition is preferably one that crosslinks upon exposure to heat, and that decrosslinks upon exposure to acid. Suitable components include hydroxy groups, carboxylic acid groups, phenolics, and/or other groups that react with vinyl ether crosslinkers. Examples of suitable compounds or monomers include those chosen from hydroxystyrene, 4-vinylphenol, methacrylic acid, 2-naphthoic acid-3-methacrylate, mono-2-(methacryloyloxy)ethylsuccinate, or combinations thereof, and/or polymers of the foregoing.

In embodiments where the component is a polymer, the weight average molecular weight of the polymer is typically about 500 Daltons to about 9,000 Daltons, and preferably about 2,000 Daltons to about 7,000 Daltons, as determined by GPC.

In addition to the above-described component, the fill composition of this embodiment includes a vinyl ether crosslinker. Suitable vinyl ether crosslinkers are preferably multi-functional (e.g., di-, tri-, or tetra-functional), such as triethylene glycol divinyl ether, 1,4-butanediol divinyl ether, 1,4-cyclohexanedimethanol divinyl ether, di(ethylene glycol) divinyl ether, poly(ethylene glycol) divinyl ether, divinyl adipate, (1,3,5-benzenetricarboxylic acid, tris [(4-ethenyloxy)butyl] ester), or combinations thereof. The structure of (1,3,5-benzenetricarboxylic acid, tris [(4-ethenyloxy)butyl] ester) is:

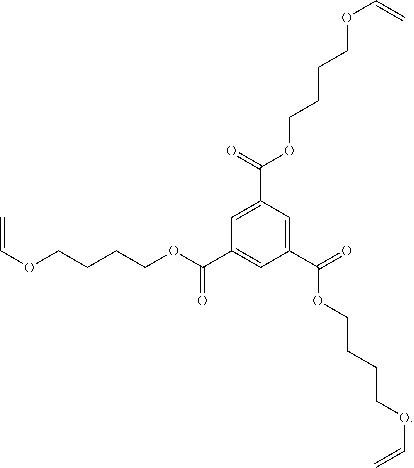 [SMILES: C=COCCCCOC(=O)c1cc(C(=O)OCCCCOC=C)cc(C(=O)OCCCCOC=C)c1]

Other crosslinkers suitable for use herein are described in U.S. Pat. No. 7,601,483, the entire contents of which are hereby incorporated by reference.

The crosslinker is preferably included at levels of about 10% by weight to about 50% by weight, preferably about 25% by weight to about 50% by weight, and more preferably about 35% by weight to about 50% by weight, based upon the total weight of the total component solids taken as 100% by weight.

The fill composition of this embodiment also includes a catalyst, which is preferably a thermal acid generator (TAG). Examples of suitable TAGs include those chosen from quaternary ammonium blocked triflic acids, benzyltriethylammonium chloride (“BTEAC”), ethyltriphenylphosphonium bromide, tetrabutylphosphonium bromide, or combinations thereof. The crosslinking catalyst is preferably present in the particular composition at levels of about 5% to about 20% by weight, more preferably about 5% to about 15% by weight, and even more preferably about 7% by weight to about 10% by weight, based upon the total weight of the component (total polymer, oligomer, and monomer) taken as 100% by weight.

The prepared formulation is used as fill composition 22, discussed previously with respect to the solubility switch method. This material can be soft baked at temperatures up to about 110° C. for about 30 seconds to about 90 seconds, with minimal to no crosslinking. After this soft bake, the material can be developed (e.g., using TMAH) or stripped using a solvent to reduce its thickness, as explained previously. Moreover, the strip rate can be controlled to facilitate removal of the desired thickness in the desired time by varying the temperature of the soft bake.

When this fill material is baked at a cure bake (e.g., about 120° C. to about 180° C. for about 45 seconds to about 60 seconds), a crosslinking reaction occurs between the hydroxy groups of the component and the vinyl groups of the crosslinker. After the cure bake, the material cannot be developed by TMAH and cannot be stripped by solvents, as explained with the method of above. However, when the material is subjected to the solubility switch bake (e.g., at a temperature above about 200° C. for about 45 seconds to about 60 seconds), acid is released from the TAG, and that acid decrosslinks the previously crosslinked component. The decrosslinked material can then be stripped by a solvent to completely remove the material.

### 3. Protecting Group

In this embodiment, the component (polymer, oligomer, and/or monomeric compound) included in the fill composition includes a protecting group that is selectively removed at the appropriate time during processing to accomplish the solubility switch. The component can be purchased commercially, or it can be synthesized, such as by polymerizing or oligomerizing a monomer containing a protecting group. Polymerization and oligomerizing can be carried out using existing methods (e.g., initiator-induced radical polymerization).

Suitable protecting groups include those chosen from methyl groups, ethyl groups, n-propyl groups, isopropyl groups, n-butyl groups, isobutyl groups, tert-butyl groups, 2-ethylhexyl groups, cyclopentyl groups, cyclohexyl groups (e.g., cyclohexyl vinyl ether), norbornyl groups, adamantyl groups, or combinations thereof. Suitable monomers with protecting groups include those chosen from tert-butyl methacrylate, 2-isopropyl-2-adamantyl methacrylate, 2-ethyl-2-adamantyl methacrylate (EM), (2-adamantyloxy)methyl methacrylate, 2-(cyanomethyl)-2-adamantyl methacrylate, 2-[(2-methyl-adamantyl)-oxy]-carbonylmethyl methacrylate, t-butoxy styrene, or combinations thereof. In the situation of an oligomer or polymer, comonomers can also be included (e.g., methacrylic acid).

In addition to the above-described component, the fill composition of this embodiment includes a crosslinker. Suitable crosslinkers are preferably multi-functional (e.g., di-, tri-, tetra-functional) and include reactive groups such as those chosen from epoxies, vinyls, or combinations thereof. Suitable crosslinkers with epoxy groups include those chosen from tetraglycidyl methylene dianiline based, tetra-functional epoxy resin crosslinkers (e.g., ARALDITE® MY 721, available from Huntsman), or combinations thereof. Suitable vinyl ether crosslinkers include those chosen from triethylene glycol divinyl ether, 1,4-butanediol divinyl ether, 1,4-cyclohexanedimethanol divinyl ether, di(ethylene glycol) divinyl ether, poly(ethylene glycol) divinyl ether, divinyl adipate, (1,3,5-benzenetricarboxylic acid, tris [(4-ethenyloxy)butyl] ester), or combinations thereof. Other crosslinkers suitable for use herein are described in previously mentioned U.S. Pat. No. 7,601,483.

The crosslinker is preferably present at levels of about 5% by weight to about 50% by weight, more preferably about 5% by weight to about 30% by weight, and even more preferably about 10% by weight to about 25% by weight, based on the total weight of total component solids taken as 100% by weight.

The fill composition of this embodiment also includes a catalyst, which is preferably a TAG. Examples of suitable TAGs include those chosen from quaternary ammonium blocked triflic acids, benzyltriethylammonium chloride, ethyltriphenylphosphonium bromide, tetrabutylphosphonium bromide, or combinations thereof. The crosslinking catalyst is preferably present in the particular composition at levels of about 0.001% to about 10% by weight, more preferably about 0.1% to about 7% by weight, and even more preferably about 0.5% by weight to about 5% by weight, based upon the total weight of the total component solids taken as 100% by weight.

The prepared formulation is used as fill composition 22, discussed previously with respect to the solubility switch method. This material can be soft baked at temperatures of about 110° C. to about 125° C. for about 30 seconds to about 120 seconds, to remove solvent with minimal to no crosslinking. At this point, the material can be removed/stripped using a developer or a solvent to reduce its thickness, as described previously. Moreover, the baking conditions (e.g., time and temperature) result in a controlled develop/stripping rate after this soft bake.

When the material is later subjected to a cure bake at about 130° C. to about 140° C. for about 45 seconds to about 60 seconds, during which some protecting groups are removed, and the component is crosslinked via crosslinks between component acid groups and crosslinker groups (e.g., vinyl groups), thus forming a crosslinked polymer. At this stage, the material cannot be developed by TMAH and cannot be stripped by solvents, as explained with the method of above. However, when the material is subjected to the solubility switch bake (e.g., at a temperature above about 160° C. for about 45 seconds to about 60 seconds), the remaining protecting groups are removed, and the TAG's acid is generated, causing a decrosslinking reaction. The material can then be stripped by a solvent to completely remove it.

### SUMMARY

It will be appreciated that the foregoing methods and chemistries provide the advantage of only using a single coating of a topographic fill material and a single develop back step while maintaining a thickness that can be controlled and sufficient to fill very deep topographies to the extent needed for lithographic patterning. The materials provide selective changes to their respective solubilities, and the methods achieve selective removal of desired amounts of the topographic fill material at various stages of the process.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Formulation Containing PEPA-FDA-PEPA Diamic Acid

In this Example, 4-(phenylethynyl) phthalic anhydride (PEPA) and 9,9′-bis(4-aminophenyl) fluorene (FDA) (2:1 molar ratio) were polymerized via a condensation reaction in propylene glycol monomethyl ether acetate (PGMEA) to form PEPA-FDA-PEPA diamic acid.

The resulting PEPA-FDA-PEPA diamic acid was mixed under ambient conditions with ARALDITE® MY 721 (tetraglycidyl methylene dianiline based, tetra-functional epoxy resin crosslinker, available from Huntsman), and R30N (nonionic surfactant, available from DIC Corporation, Japan) in PGMEA. The resulting formulation comprised 18.16% by weight polymer solids, 1.82% by weight crosslinker, 0.09% by weight surfactant, and 79.93% by weight solvent system.

The coating solutions were spin coated on wafers with deep trenches at 1,500 rpm for 60 seconds. The coated wafers are baked at 120° C. for 60 seconds to remove the coating solvent. At this stage, the PEPA-FDA-PEPA diamic acid was only partially crosslinked. If needed, the coating could still be stripped by a solvent (e.g., propylene glycol methyl ether, propylene glycol methyl ether acetate, cyclohexanone, cyclopentanone, n-methyl pyrrolidone, gamma butyrolactone) to remove overburden on top of trenches.

Next, the wafers are baked at 180° C. for 1 minute so that PEPA-FDA-PEPA diamic acid was fully crosslinked between the carboxyl groups of the diamic acid and the epoxy groups of the MY721 crosslinker to form amic esters. A photoresist was spin coated on top of the formed gap fill layer and baked. After the photoresist processing step, the wafers were baked above 210° C., the amic esters are imidized (i.e., converted to imides), which caused decrosslinking, thus allowing the gap fill coating to be removed by a solvent.

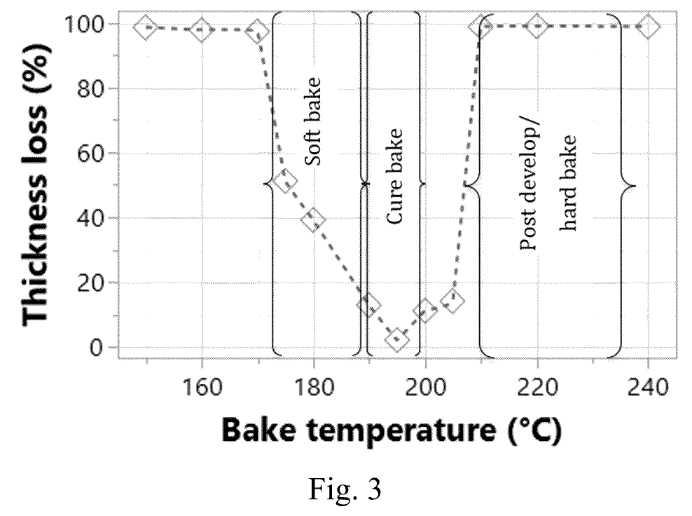

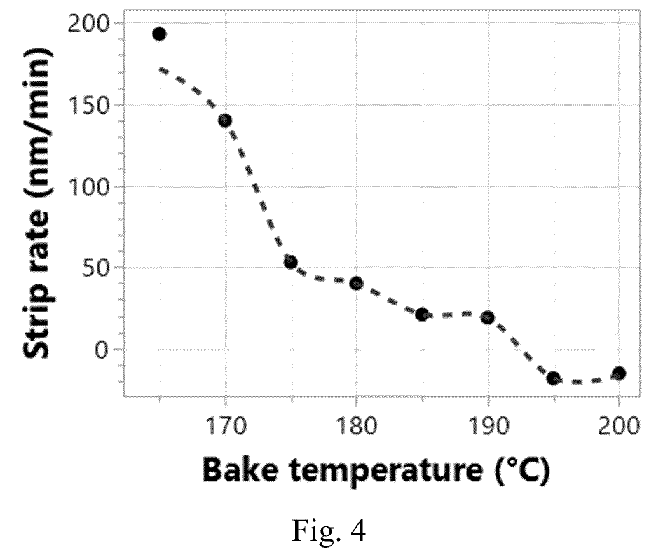

Spinners and hotplates (sold by Cost Effective Equipment LLC, St. James, MO) were used to prepare and strip wafers. Thicknesses were measured with an ellipsometer (sold by Gaertner Scientific Corporation). FIG. 3 shows thickness loss vs. bake temperature, and FIG. 4 shows strip rate in PGMEA vs. bake temperature for the material of this Example. As demonstrated by FIG. 4, the material could be controllably recessed in PGMEA when baked at about 165° C. to about 180° C.

### Example 2

### Formulation Containing Polyhydroxystyrene

Commercially available polyhydroxystyrene (PHS; VP-2500 Nippon Soda Co., Ltd.) having a Mw of 2,500 Daltons was blended in a solvent system with 1,3,5-benzenetricarboxylic acid, tris [(4-ethenyloxy)butyl] ester, K-PURE TAG 2689 (a quaternary ammonium blocked triflic acid thermal acid generator, available from King Industries), vinyl ether crosslinking agent (1,3,5-benzenetricarboxylic acid, tris [(4-ethenyloxy)butyl] ester), and surfactant (R30N) to achieve a final formulation consisting of 45% by weight vinyl ether crosslinking agent, 7% by weight TAG, and 0.1% by weight surfactant, based on the weight of PHS polymer solids (21.04%). The solvent system was included in the formulation at a level of 68% by weight and consisted of 40.8% by weight propylene glycol monomethyl ether (PGME) and 27.2% by weight PGMEA.

The coating solution was spin coated on wafers with deep trenches at 1,500 rpm for 60 seconds. The material was baked at a temperature of 110° C. and then recessed using PGMEA. Next, the material was baked at a 160° C. (but can be selected from a temperature range of 120° C. to 180° C.), after which the material was solvent stable (i.e., it did not strip). That is, the phenol group on the polymer had reacted with the vinyl groups of the crosslinker to form a crosslinked polymer. The material was then baked at 200° C. (can be selected from 200° C. or above), during which decrosslinking took place, and the material was fully soluble in TMAH developer, as shown by traditional curve vs. bake. Schematic A shows the general reactions that took place in this Example.

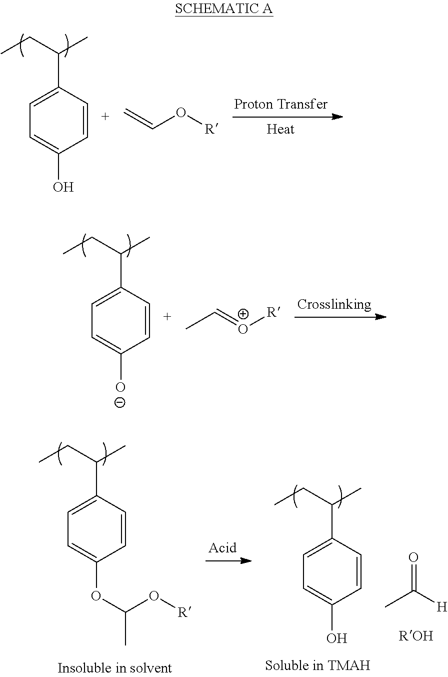

Spinners and hotplates (sold by Cost Effective Equipment LLC, St. James, MO) were used to prepare and strip wafers. Thicknesses were measured with an ellipsometer (sold by Gaertner Scientific Corporation).

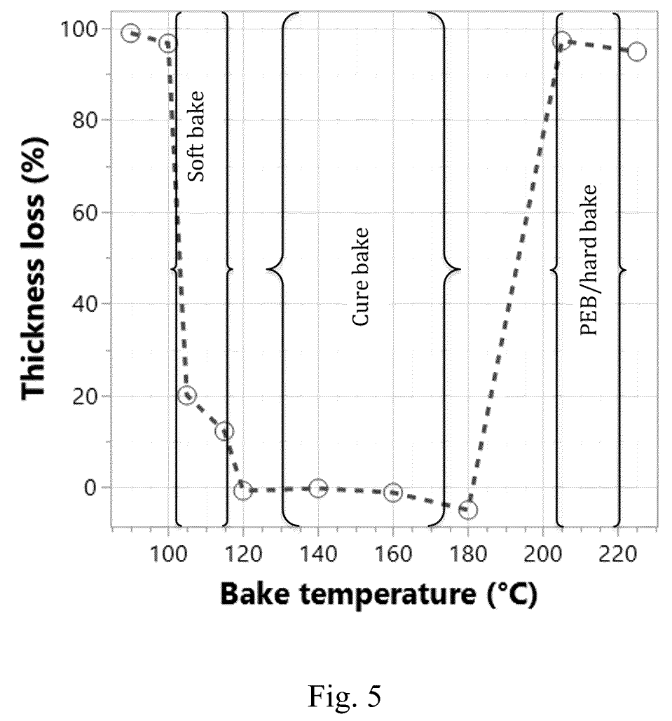

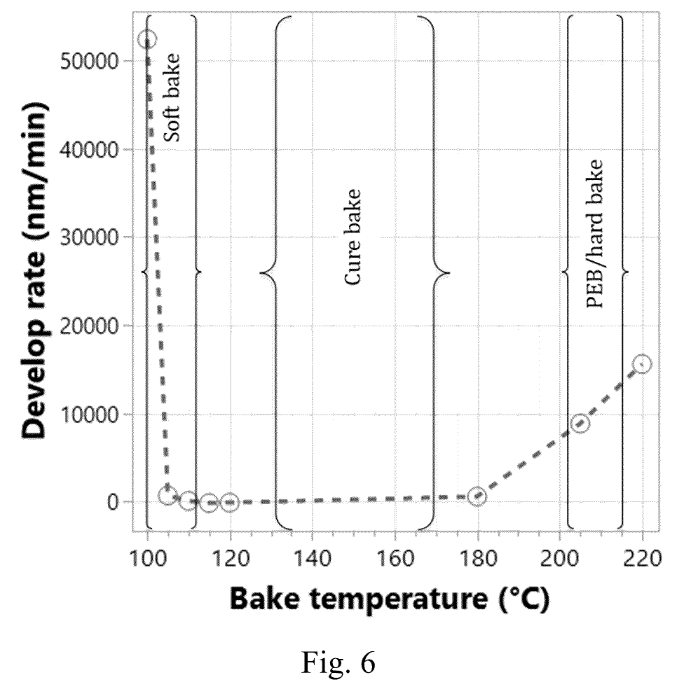

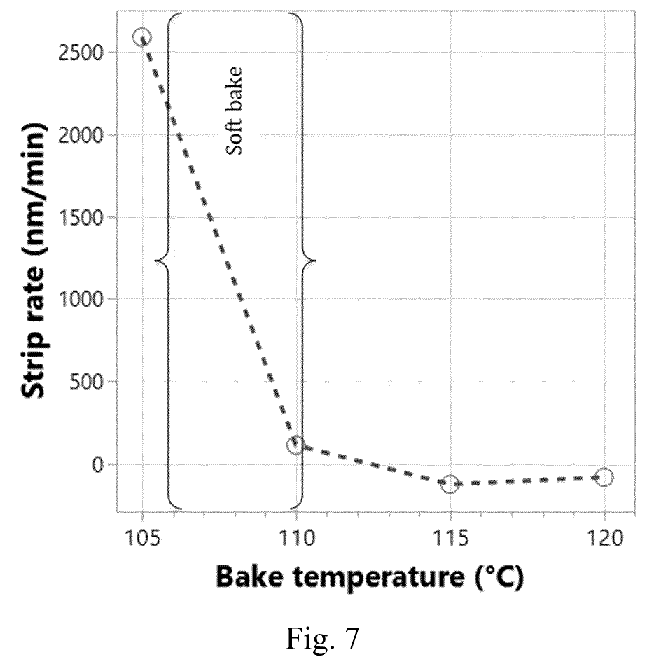

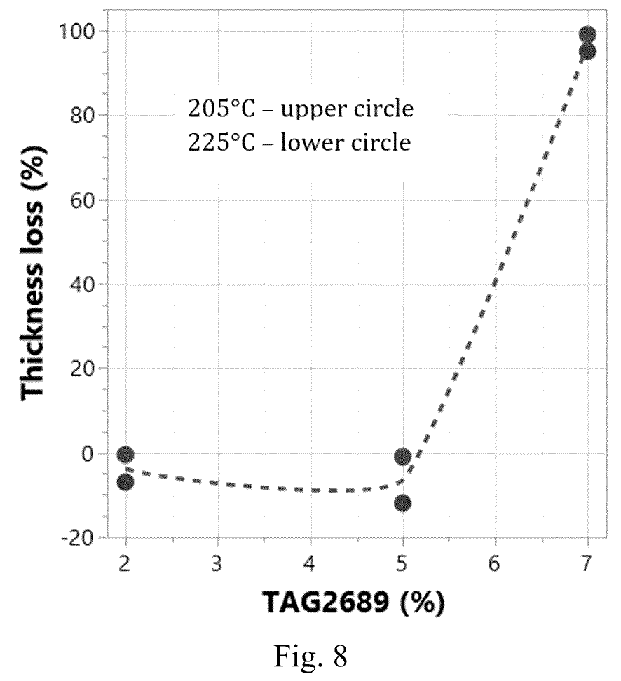

FIGS. 5-8 provide graphs depicting the influence of bake temperature and TAG loading for the material of this Example. FIG. 5 shows that the material became solvent/photoresist compatible when baked at about 120° C. to about 180° C. FIG. 6 demonstrates that the material became fully soluble in TMAH after baking at greater than about 200° C. As demonstrated by FIG. 7, the material could be controllably recessed in PGMEA when baked at about 110° C. Finally, FIG. 8 shows how the solubility of the material in TMAH increased with TAG loading.

### Example 3

### Formulation Containing Methacrylate Terpolymer

A methacrylate polymer was synthesized by a radical reaction using styrene (TCI America), tert-butyl methacrylate (TCI America), and methacrylic acid (TCI America) monomers in a 2.5:1:1.5 molar ratio. Azobisisobutyronitrile (AIBN) (Sigma Aldrich) was used as the initiator, and the reaction solvent was PGMEA. The reaction was carried out at 75° C. for 24 hours.

The material was formulated by mixing the methacrylate polymer with 15% by weight 1,3,5-benzenetricarboxylic acid, tris [(4-ethenyloxy)butyl] ester as a crosslinker, 1% by weight TAG2689 as a catalyst, and 0.1% by weight R30N as a surfactant, based on the weight of methacrylate polymer solids. The formulation comprised 23.81% by weight polymer solids and 76.19% by weight solvent system (20% by weight PGME and 80% by weight PGMEA).

The coating solutions were spin coated on wafers with deep trenches at 1,500 rpm for 60 seconds. The coated wafers were then baked at 120° C. for 60 seconds to remove the coating solvent. At this stage, the polymer was only partially crosslinked and could still be stripped by a solvent to remove overburden on top of trenches. Next, the wafers were baked at 140° C., so that the polymer was fully crosslinked between the acid groups on the polymer and the vinyl groups on the 1,3,5-benzenetricarboxylic acid, tris [(4-ethenyloxy)butyl] ester to form a crosslinked polymer.

A photoresist (FHi560-EP from FUJIFILM Electronic Materials U.S.A., Inc.) was spin coated on top of the formed gap fill layer at 1,500 rpm for 30 seconds followed by baking at 120° C. for 1 minute. After the photoresist processing step, the wafers were baked above 160° C., during which the acid was deprotected by residual acid and heat, which caused the decrosslinking reaction, thus allowing the gap fill coating to be removed by a developer.

1. A topographic fill method comprising:
applying a fill composition over a pattern comprising a plurality of gaps in a substrate so as to deposit said fill composition in at least some of said gaps, said fill composition:
comprising a component chosen from one or more of polymers, oligomers, or monomeric compounds, said component being dispersed or dissolved in a solvent system having an evaporation temperature; and
having a crosslinking temperature at which said component begins to crosslink;
heating said fill composition to about said evaporation temperature or higher, but lower than said crosslinking temperature, so as to remove at least some of said solvent system and form a dried composition;
contacting said dried composition with a developer solvent so as to remove at least some of said dried composition;
after said contacting, doing one of (a) or (b):
(a) heating said dried composition to said crosslinking temperature or higher so as to cause said component to crosslink and form a crosslinked fill material that is substantially insoluble in said developer solvent; and
forming a photoresist layer on said crosslinked fill material; or
(b) forming a photoresist layer on said dried composition; and
then heating said dried composition to said crosslinking temperature or higher so as to cause said component to crosslink and form a crosslinked fill material that is substantially insoluble in said developer solvent; and
selectively exposing said photoresist layer to radiation; and
heating said crosslinked fill material at a temperature that is about 10° C. or more above said crosslinking temperature for a sufficient time so as to cause said crosslinked fill material to become soluble in said developer solvent and form a soluble fill material.

2. The method of claim 1, wherein said fill composition further comprises a crosslinker and said component is chosen from one or more of diamic acids or polyamic acids.

3. The method of claim 2, wherein:
said polyamic acid is formed from a dianhydride and a diamine;
said diamic acid is formed from a dianhydride and a monoamine, or a monoanhydride and a diamine;
said dianhydride is chosen from benzophenone-3,3′4,4′-tetracarboxylic dianhydride, 4,4′-oxydiphthalic dianhydride, 9,9-bis(3,4-dicarboxyphenyl) fluorene dianhydride, or combinations thereof;
said monoamine is chosen from 2-vinylaniline, 4-vinylaniline, 2-allylaniline, 4-allylaniline, 3-ethynylaniline, 4-ethynylaniline, 2-ethynylaniline or combinations thereof;
said monoanhydride is chosen from maleic anhydride, 4-cyclohexene-1,2-dicarboxylic anhydride, 5-norbornene-2,3-dicarboxylic anhydride, 4-ethynyl phthalic anhydride, 4-methylethynyl phthalic anhydride, 4-phenylethynyl phthalic anhydride, or combinations thereof; and
said diamine is chosen from 4,4′-oxydianiline, bis(4-aminophenyl) sulfone, 9,9-bis(4-aminophenyl) fluorene, or combinations thereof.

4. The method of claim 2, wherein said heating of said fill composition to about said evaporation temperature or higher comprises heating to a temperature of up to about 130° C. for about 45 seconds to about 60 seconds.

5. The method of claim 2, wherein said heating of said dried composition to said crosslinking temperature or higher comprises heating to a temperature of about 180° C. to about 200° C. for about 45 seconds to about 60 seconds.

6. The method of claim 2, wherein said heating of said crosslinked fill material to cause said crosslinked fill composition to become soluble comprises heating to a temperature of about 210° C. or higher for about 45 seconds to about 60 seconds.

7. The method of claim 2, wherein said heating of said crosslinked fill material to cause said crosslinked fill composition to become soluble causes:
(i) said diamic acid to imidize and form a diimide;
(ii) said polyamic acid to imidize and form a polyimide; or
(iii) both (i) and (ii).

8. The method of claim 1, wherein:
said fill composition further comprises a vinyl ether crosslinker and a thermal acid generator; and
said component comprises one or more groups that react with said vinyl ether crosslinker.

9. The method of claim 8, wherein:
said component comprises:
hydroxystyrene, 4-vinylphenol, methacrylic acid, 2-naphthoic acid-3-methacrylate, mono-2-(methacryloyloxy)ethylsuccinate, or combinations thereof;
one or both of a polymer or oligomer comprising hydroxystyrene monomers, 4-vinylphenol monomers, methacrylic acid monomers, 2-naphthoic acid-3-methacrylate monomers, mono-2-(methacryloyloxy)ethylsuccinate monomers, or combinations thereof; and
said vinyl ether crosslinker is chosen from triethylene glycol divinyl ether, 1,4-butanediol divinyl ether, 1,4-cyclohexanedimethanol divinyl ether, di(ethylene glycol) divinyl ether, poly(ethylene glycol) divinyl ether, divinyl adipate, (1,3,5-benzenetricarboxylic acid, tris [(4-ethenyloxy)butyl] ester), or combinations thereof.

10. The method of claim 8, wherein said heating of said fill composition to about said evaporation temperature or higher comprises heating to a temperature of up to about 110° C. for about 30 seconds to about 90 seconds.

11. The method of claim 8, wherein said heating of said dried composition to said crosslinking temperature or higher comprises heating to a temperature of about 120° C. to about 180° C. for about 45 seconds to about 60 seconds.

12. The method of claim 8, wherein said heating of said crosslinked fill material to cause said crosslinked fill composition to become soluble comprises heating to a temperature of about 200° C. or higher for about 45 seconds to about 60 seconds.

13. The method of claim 8, wherein during said heating of said crosslinked fill material to cause said crosslinked fill composition to become soluble, said component decrosslinks and forms a decrosslinked fill material that is substantially soluble in said developer solvent.

14. The method of claim 1, wherein:
said fill composition further comprises a crosslinker and a thermal acid generator; and
said component comprises a protecting group.

15. The method of claim 14, wherein:
said component comprises:
tert-butyl methacrylate, 2-isopropyl-2-adamantyl methacrylate, 2-ethyl-2-adamantyl methacrylate, (2-adamantyloxy)methyl methacrylate, 2-(cyanomethyl)-2-adamantyl methacrylate, 2-[(2-methyl-adamantyl)-oxy]-carbonylmethyl methacrylate, tert-butoxy styrene, or combinations thereof; and/or
one or both of a polymer or oligomer comprising tert-butyl methacrylate, 2-isopropyl-2-adamantyl methacrylate, 2-ethyl-2-adamantyl methacrylate, (2-adamantyloxy)methyl methacrylate, 2-(cyanomethyl)-2-adamantyl methacrylate, 2-[(2-methyl-adamantyl)-oxy]-carbonylmethyl methacrylate, tert-butoxy styrene, or combinations thereof; and
said crosslinker is chosen from tetra-functional epoxy resins, triethylene glycol divinyl ether, 1,4-butanediol divinyl ether, 1,4-cyclohexanedimethanol divinyl ether, di(ethylene glycol) divinyl ether, poly(ethylene glycol) divinyl ether, divinyl adipate, (1,3,5-benzenetricarboxylic acid, tris [(4-ethenyloxy)butyl] ester), 1H-pyrrole-2,5-dione, 1,1′-C36-alkylenebis-, or combinations thereof.

16. The method of claim 14, wherein said heating of said fill composition to about said evaporation temperature or higher comprises heating to a temperature of up to about 110° C. for about 30 seconds to about 120 seconds.

17. The method of claim 14, wherein said heating of said dried composition to said crosslinking temperature or higher comprises heating to a temperature of about 130° C. to about 140° C. for about 45 seconds to about 60 seconds.

18. The method of claim 14, wherein said heating of said crosslinked fill material to cause said crosslinked fill composition to become soluble comprises heating to a temperature of about 160° C. or higher for about 45 seconds to about 60 seconds.

19. The method of claim 14, wherein during said heating of said crosslinked fill material to cause said crosslinked fill composition to become soluble, an acid is generated from said thermal acid generator, and said acid decrosslinks said component to form a decrosslinked fill material that is substantially soluble in said developer solvent.

20. The method of claim 1, further comprising removing said soluble fill material with said developer solvent.

21. The method of claim 1, wherein said fill composition is non-photosensitive.

22. The method of claim 1, wherein neither of said dried composition or said crosslinked fill material are subjected to plasma etching.

23. The method of claim 1, wherein only a single photoresist layer is formed.

24. The method of claim 1, wherein said photoresist layer is exposed to radiation only one time.

25. The method of claim 1, wherein said developer solvent is chosen from tetramethylammonium hydroxide, propylene glycol methyl ether acetate, propylene glycol methyl ether, ethyl lactate, n-butyl acetate, or combinations thereof.
